(19) United States
(12) Patent Application Publication
(10) Pub. No.: US 2011/0111628 A1
(43) Pub. Date: May 12, 2011

(54) CABLE ASSEMBLY AND METHOD OF MANUFACTURING THE SAME

(75) Inventors: PING-SHENG SU, Tu-Cheng (TW); XIAO-LI LI, Kunshan (CN)

(73) Assignee: HON HAI PRECISION INDUSTRY CO., LTD., Tu-Cheng (TW)

(21) Appl. No.: 12/943,031

(22) Filed: Nov. 10, 2010

(30) Foreign Application Priority Data
Nov. 10, 2009 (CN) 200910309492.1

(51) Int. Cl. H01R 13/648; H01R 24/00; H05K 3/00

(52) U.S. Cl. 439/607.01; 439/660; 29/842

(57) ABSTRACT

A cable assembly (100 comprises an insulative housing (1) having a recess (12) formed on a rear surface thereof; a plurality of contacts (2) disposed in the insulative housing; a printed circuit board (3) having a front portion received into the recess and electrically connected with the plurality of contacts, the printed circuit board having a first PCB and a second PCB stacked together in a manner of back to back; a shielding member (5) enclosing the housing and the printed circuit board; and a cable (4) having a plurality of conductive wires (41) extending into the shielding member and electrically connected to a rear portion of the printed circuit board.

### FIELD OF THE INVENTION

The present invention relates to a cable assembly, and more particularly to a cable which is easily manufactured.

### DESCRIPTION OF PRIOR ART

Presently, a printed circuit board is widely used in a cable assembly for electrically connecting a plurality of contacts to a cable. China Pat. No. 2711949Y issued to YangLi ShuLan on Jul. 20, 2005 discloses an electrical connector. The electrical connector comprises a shell, a housing received into the shell, a plurality of contacts held in the housing, a printed circuit board having a front end electrically connected with the plurality of contacts and a cable electrically connected with a rear end of the printed circuit board. It should be noted that the cable has a plurality of conductive wires respectively electrically connected to a top and bottom surfaces of the rear end of the printed circuit board. Thus, the electrical connector further comprises a pair of stacked wire management members to hold the conductive wires. As a result, the conductive wires are easily soldered to the printed circuit board.

However, a plurality of conductive wires of the cable completely electrically connected to the printed circuit board needs two-times soldering. A plurality of conductive wires are soldered to the top surface of the printed circuit board through one-time soldering. A plurality of conductive wires are soldered to the bottom surface of the printed circuit board through another-time soldering. Thus, an connection between the cable and the printed circuit board will not be achieved through only one-time soldering. So, two-times soldering will be spent in an assembling process of the electrical connector. In addition, the electrical connector further defines a pair of wire management members for holding and positioning the conductive wires of the cable. Thus, a manufacturing cost of the electrical connector will also be increased.

As discussed above, an improved cable assembly overcoming the shortages of existing technology is needed.

### SUMMARY OF THE INVENTION

Accordingly, an object of the present invention is to provide a cable assembly which is easily assembled and with a lower manufacturing cost.

In order to achieve the above-mentioned objects, a cable assembly comprises an insulative housing having a recess formed on a rear surface thereof; a plurality of contacts disposed in the insulative housing; a printed circuit board having a front portion received into the recess and electrically connected with the plurality of contacts, the printed circuit board having a first PCB and a second PCB stacked together in a manner of back to back; a shielding member enclosing the housing and the printed circuit board; and a cable having a plurality of conductive wires extending into the shielding member and electrically connected to a rear portion of the printed circuit board.

Other objects, features and advantages of the invention will be apparent from the following detailed description taken in connection with the accompanying drawings.

### BRIEF DESCRIPTION OF THE DRAWINGS

FIG. 1 is a perspective view of a cable assembly in accordance with the present invention;

FIG. 2 is exploded, perspective view of the cable assembly of FIG. 1;

FIG. 3 is a partial assembled, perspective view of the cable assembly in accordance with the present invention;

FIG. 4 is a partial exploded, perspective view of the cable assembly of FIG. 3;

FIG. 5 is a cross section view of the cable assembly of FIG. 1 taken along line 5-5;

FIG. 6 is a perspective view of the wire management member, a plurality of conductive wires and a pair of PCBs assembled together;

FIG. 7 is similar to FIG. 6, but viewed from another aspect.

### DETAILED DESCRIPTION OF PREFERRED EMBODIMENTS

Reference will now be made to the drawing figures to describe the present invention in detail.

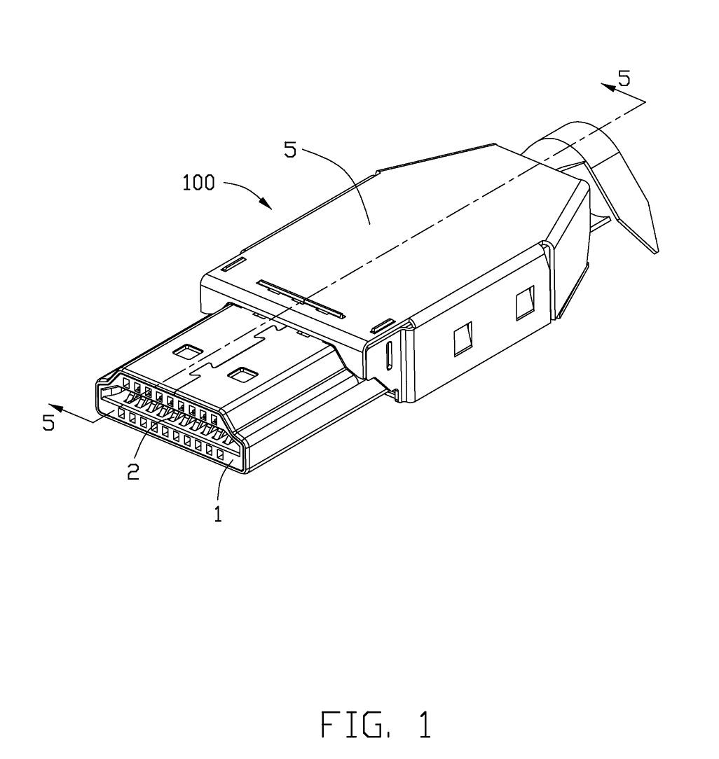

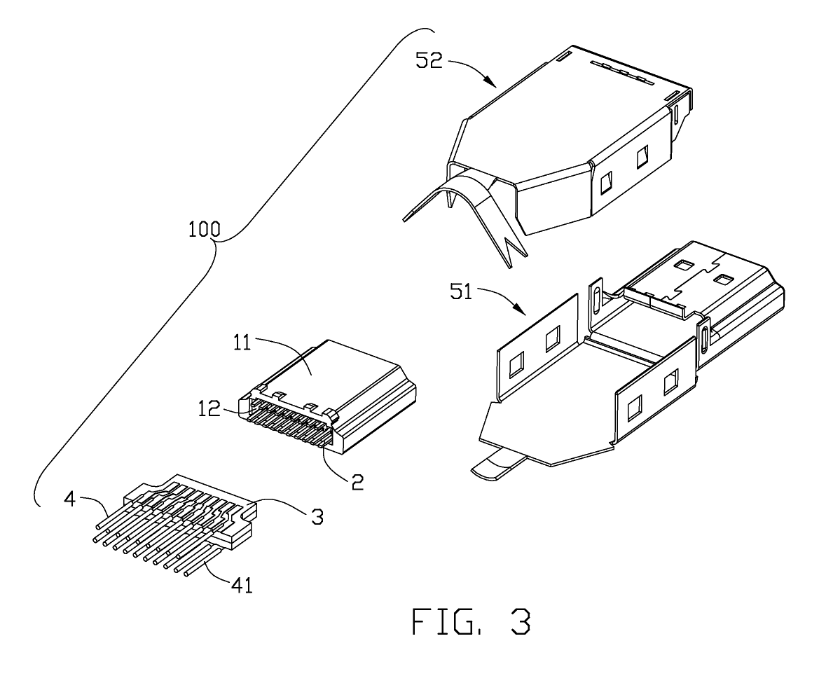

Please refer to FIGS. 1 to 3 and 5, a cable assembly 100 made in accordance with the present invention comprises an insulative housing 1, a plurality of contacts 2 disposed in the insulative housing 1, a printed circuit board 3 having a front section received into the insulative housing 1 and electrically connected with the plurality of contacts 2 and a shielding member 5 surrounding the insulative housing 1 and the printed circuit board 3. The cable assembly 100 further comprises a cable 4 extending into the insulative housing 1 and electrically connected with a rear end of the printed circuit board 3. And, the printed circuit board 3 includes a first PCB 31 and a second PCB 32 stacked together in a manner of back to back.

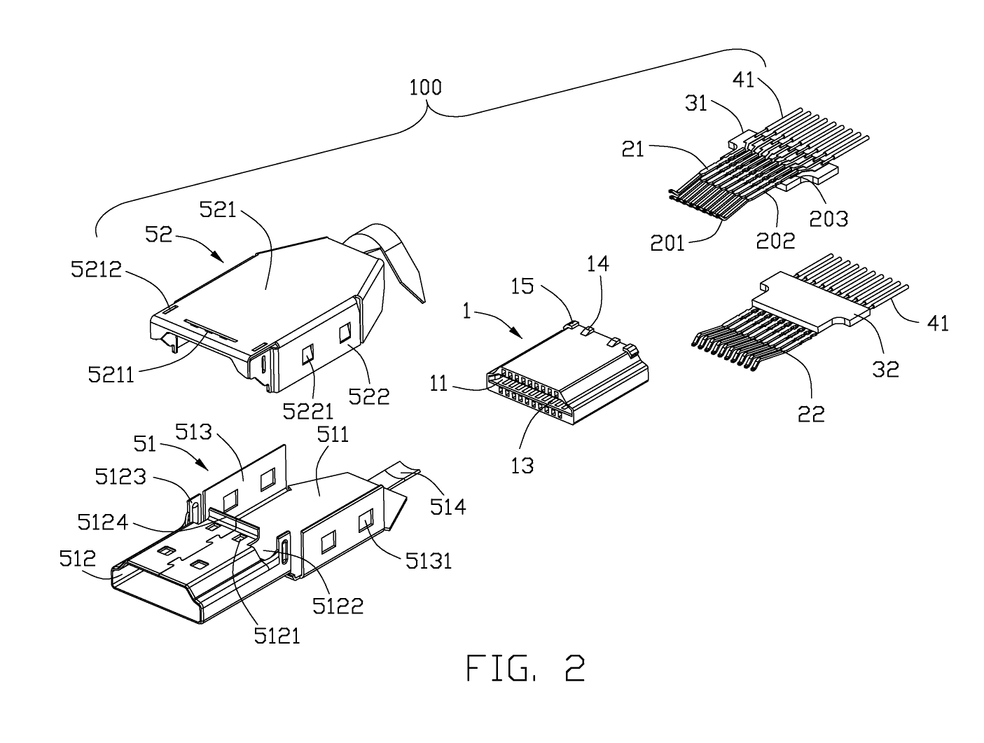

Referring to FIGS. 2 to 4, the insulative housing 1 defines a front surface and a rear surface opposite to the front surface. The insulative housing 1 defines a receiving cavity 11 extending rearward from the front surface thereof for a distance. The insulative housing 1 further defines a recess 12 formed on the rear surface thereof. The insulative housing 1 defines a plurality of passageways 13 divided into a first row and a second row paralleled with each other. A first row of passageways 13 are formed on a top inner surfaces of the receiving cavity 11 and the recess 12. A second row of passageways 13 are formed on a bottom inner surfaces of the receiving cavity 11 and the recess 12. The receiving cavity 11 communicates with the recess 12 in a front to rear direction by the plurality of passageways 13. The insulative housing 1 further defines a pair of protruding pieces 14 on a top surface thereof for locking with the shielding member 5 and a pair of protrusions 15 disposed at two sides of the pair of protruding pieces 14 for limiting a rearward movement of the shielding member 5.

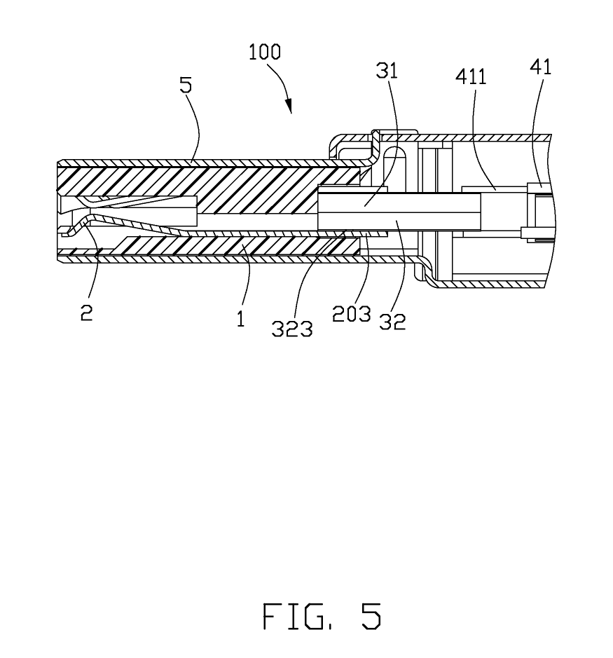

Referring to FIGS. 2 and 5, the plurality of contacts 2 are divided into a first set of contacts 21 and a second set of contacts 22. And, the first set of contacts 21 is received into the first row of passageways 13 and positioned with the insulative housing 1. The second set of contacts 22 is received into the second row of passageways 13 and positioned with the insulative housing 1. Each contact 2 defines an elastic and curved mating section 201 disposed in the passageway 13, a terminating section 203 beyond the rear surface of the insulative housing 1 and a connecting section 202 connected with the mating section 201 and the terminating section 203. Each connecting section 202 of the contact 2 is interfered with a corresponding passageway 13 to make the contact 2 positioned with the insulative housing 1.

Referring to FIGS. 2 to 3 and 5 to 7, the printed circuit board 3 includes a first PCB 31 and a second PCB 32 assembled together in a manner of back to back. The first PCB 31 has a front portion 311 and a rear portion 312. The rear portion 312 has a width larger than that of the front portion 311. The first PCB 31 has a top surface and a bottom surface opposite to the top surface. The front portion 311 of the first PCB 31 defines a plurality of front conductive pads 313 formed on the top surface thereof. The rear portion 312 of the first PCB 31 defines a plurality of rear conductive pads 314 formed on the top surface thereof. The plurality of front and rear conductive pads 313, 314 of the first PCB 31 are respectively arranged along a transversal direction. A distance between two adjacent rear conductive pads 314 is larger than a distance between two adjacent front conductive pads 313. And, the second PCB 32 has a similar structure to the first PCB 31 and also has a top surface and a bottom surface opposite to the top surface. The second PCB 32 has a front portion 321 and a rear portion 322. The rear portion 322 also has a width larger than that of the front portion 321. A plurality of front conductive pads 323 and rear conductive pads 324 are respectively formed on a top surface of the front portion 321 and the rear portion 322 of the second PCB 32. The plurality of front and rear conductive pads 323, 324 of the second PCB 32 are respectively arranged along a transversal direction. A distance between two adjacent rear conductive pads 324 is larger than a distance between two adjacent front conductive pads 323. The printed circuit board 3 is formed by the first and second PCBs 31, 32 stacked with each other. The bottom surface of the second PCB 32 is attached to the bottom surface of the first PCB 31. Thus, the printed circuit board 3 defines a front portion formed by two front portions 311, 321 of the first and second PCBs 31, 32 and a rear portion formed by two rear portions 312, 322 of the first and second PCBs 31, 32. A width of the rear portion of the printed circuit board 3 is larger than a width of the front portion of the printed circuit board 3. And, the front conductive pads 313, 323 are respectively formed on a top and bottom surfaces of the front portion of the printed circuit board 3. The rear conductive pads 314, 324 are also respectively formed on a top and bottom surfaces of the rear portion of the printed circuit board 3.

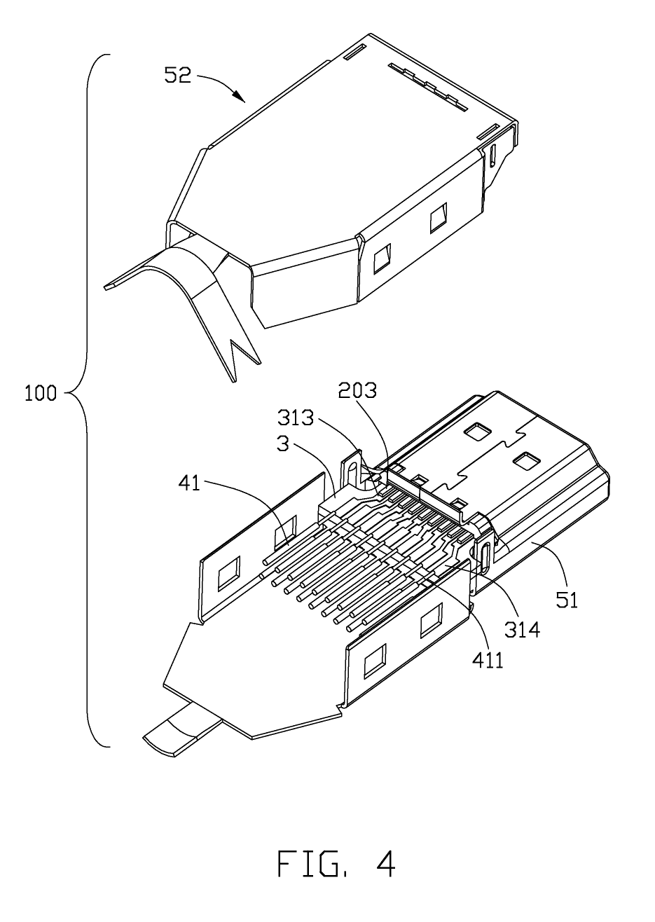

Referring to FIGS. 4 to 6, the cable 4 has a plurality of conductive wires 41 electrically connected to a rear portion of the printed circuit board 3. Each conductive wire 41 has a conductor 411 electrically connected to a rear conductive pad 314 or 324.

Referring to FIGS. 1 to 5, the shielding member 5 comprises a first shell 51 and a second shell 52 assembled to the first shell 51 along an up to down direction. The first shell 51 defines a bottom wall 511, a box portion 512 formed at a front portion of the bottom 511, a pair of first side walls 513 extending upwardly from two sides of the bottom wall 511 and a supporting portion 514 extending rearwardly from a rear end of the bottom wall 511. The pair of first side walls 513 are located in back of the box portion 512 and spaced apart with the box portion 512 along a front to rear direction. Each first side wall 513 defines two rectangular holes 5131 thereof. The box portion 512 has a receiving room extending long a front a to rear direction for receiving the insulative housing 1. The box portion 512 defines a pair of openings 5121 formed on a top side (not figured) thereof. A pair of cutouts 5122 are also formed on the top side of the box portion 512 and respectively disposed at two side of the two openings 5121. The box portion 512 further defines a first vertical plate 5124 formed on a top side thereof and a pair of second vertical plates 5123 formed at two sides thereof. The second shell 52 defines a top wall 521 and a pair of second side walls 522 extending downwardly from two sides of the top wall 521. The top wall 521 of the second shell 52 has a first slit 5211 extending along a transversal direction and a pair of second slits 5212 extending along a longitudinal direction and disposed at two sides of the first slit 5211. The first and second vertical plates 5124, 5123 can respectively pass through the first slit 5211 and the second slit 5212 when the second shell 52 is assembled to the first shell 51. Each second side wall 522 of the second shell 52 has two inclined locking pieces 5221 cooperated with the two corresponding rectangular holes 5131.

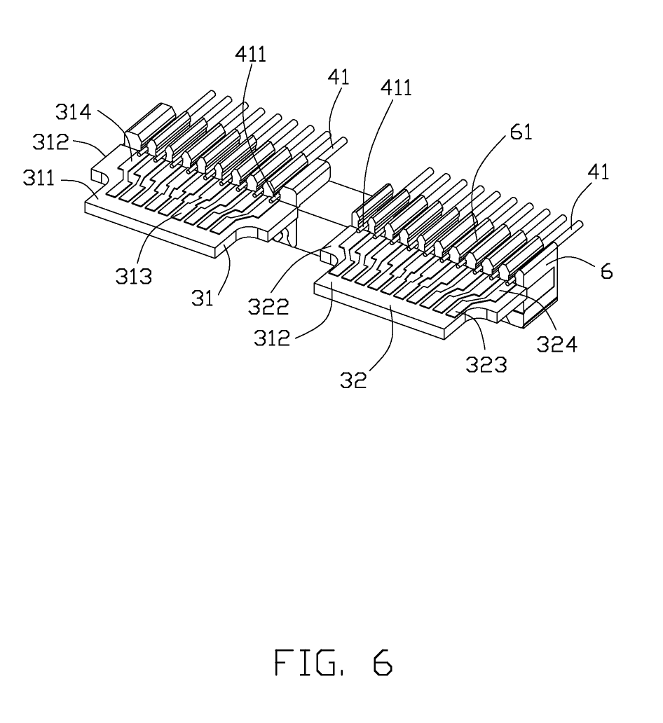

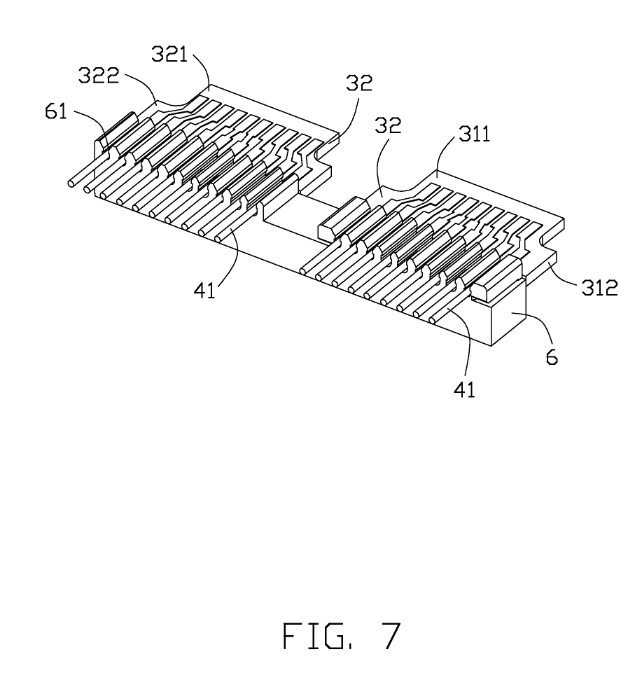

Referring to FIGS. 6 and 7, a wire management member 6 is used to achieve an electrical and mechanical connection between the conductive wires 41 of the cable 4 and the first and second PCBs 31, 32. The wire management member 6 defines a plurality of slots 61 extending along a front to rear direction and arranged along a transversal direction for accepting and managing the plurality of conductive wires 41. The plurality of slots 61 are divided into two groups. The first and second PCBs 31, 32 can be arranged in front of the wire management member 6 and respectively in alignment with a group of slots 61. And, a group of slots 61 has an number equal to that of the rear conductive pads 314 of the first PCB 31. Another group of slots 61 has a number equal to that of the rear conductive pads 324 of the second PCB 32. The rear conductive pads 314 of the first PCB 31 are respectively in alignment with a slot of the group of slots 61 along a front to rear direction. The rear conductive pads 324 of the second PCB 32 are respectively in alignment with a slot of another group of slots 61 along a front to rear direction. Thus, the conductive wires 41 of the cable 4 can be electrically connected to the first and second PCBs 31, 32 through one-time soldering.

Referring to FIGS. 1 to 7, the assembling process of the cable assembly 100 made in according to the present invention starts from assembling a plurality of contacts 2 to the corresponding passageways 13 of the insulative housing 1. And, the mating section 201 of each contact 2 extends into the receiving cavity 11 of the insulative housing 1. The terminating section 203 of each contact 2 extends into the recess 12 of the insulative housing 1 and has a rear end beyond the rear surface of the housing 1.

After the plurality of contacts 2 are received into the housing 1, then connecting the plurality of conductive wires 41 of the cable 4 to the rear end of the printed circuit board 3 through one-time soldering. And, the electrical and mechanical connection between the printed circuit board 3 and the cable 4 will be achieved through several assembling steps. The several assembling steps comprises, firstly, providing a wire management member 6 having a plurality of slots 61 formed on a top surface thereof for accepting and positioning the plurality of conductive wires 41; secondly, providing a holding tool (not shown) to make the first and second PCBs 31, 32 located in front of the wire management member 6 and the rear conductive pads 314, 324 of first and second PCBs 31, 32 in alignment with the slots 61 of the wire management member 6 along a front to rear direction; thirdly, assembling the plurality of conductive wires 41 to the wire management member 6; fourthly, soldering the plurality of conductors 411 of the wires 41 to the rear conductive pads 314, 324 of the printed circuit board 3 through hotbar process; at last, removing the first and second PCBs 31, 32 and the cable 4 from the holding tool and stacking the first and second PCBs 31, 32 in a back to back manner.

After the cable 4 is assembled to the printed circuit board 3, then assembling a front portion of the printed circuit board 3 to the recess 12 of the insulative housing 1. Each rear end of the terminating section 203 of the contact 2 is disposed upon the corresponding front conductive pad 313, 323.

After the printed circuit board 3 is assembled to the insulative housing 1, then soldering the terminating sections 203 of the contacts 2 to the corresponding front conductive pads 313, 323 of the printed circuit board 3. Thus, the plurality of contacts 5 are electrically connected with the cable 4 by the printed circuit board 3.

Finally, assembling the first shell 51 to the housing 1 along a front to rear direction, and assembling the second shell 52 to the first shell 51 along an up to down direction. Thus, the shielding member 5 is formed by the first and second shell 51, 52 engaged with each other. The insulative housing 1 and the printed circuit board 3 are enclosed by the shielding member 5.

After the above assembling steps, the entire process of assembling the cable assembly 100 is finished.

It should be noted that the plurality of conductive wires 41 of the cable 4 electrically and mechanical connect to the first and second PCBs 31, 32 using one time of soldering. So, an entire time of assembling the cable assembly 100 will be short compared to the prior art. On another aspect, the cable assembly 100 does not have a pair of wire management members therein. So, a cost of the cable assembly 100 will be reduced compared to the prior art.

It will be understood that the invention may be embodied in other specific forms without departing from the spirit or central characteristics thereof. The present examples and embodiments, therefore, are to be considered in all respects as illustrative and not restrictive, and the invention is not to be limited to the details given herein.

What is claimed is:

1. A cable assembly, comprising:
an insulative housing having a recess formed on a rear surface thereof;
a plurality of contacts disposed in the insulative housing;
a printed circuit board having a front portion received into the recess and electrically connected with the plurality of contacts, the printed circuit board having a first PCB and a second PCB stacked together in a manner of back to back;
a shielding member enclosing the housing and the printed circuit board; and
a cable having a plurality of conductive wires extending into the shielding member and electrically connected to a rear portion of the printed circuit board.

2. The cable assembly as recited in claim 1, wherein the front portion defines a plurality of front conductive pads formed on two opposite top and bottom surfaces thereof, the rear portion defines a plurality of rear conductive pads formed on two opposite top and bottom surfaces thereof.

3. The cable assembly as recited in claim 2, wherein each contact has a terminating section electrically connected to a front conductive pad of the printed circuit board, and each conductive wire has a conductor therein electrically connected to a rear conductive pad of the printed circuit board.

4. The cable assembly as recited in claim 2, wherein the rear portion of the printed circuit board has a width larger than that of the front portion of the printed circuit board.

5. The cable assembly as recited in claim 2, wherein a width between two adjacent front conductive pads is smaller than a width between two adjacent rear conductive pads.

6. The cable assembly as recited in claim 1, wherein the housing defines a receiving cavity extending rearwardly from a front surface thereof for a distance, each contact defines an elastic mating section extending into the receiving cavity.

7. The cable assembly as recited in claim 6, wherein the housing defines a plurality of passageways on two opposite inner surfaces of the receiving cavity and the recess, each contact is received into a corresponding passageway.

8. The cable assembly as recited in claim 1, wherein the shielding member comprises a first shell and a second shell assembled together.

9. The cable assembly as recited in claim 8, wherein the first shell defines a bottom wall, a box portion formed at a front end of the bottom wall and enclosing the insulative housing, a pair of first side walls extending upwardly from two sides of the bottom wall, the box portion is spaced apart with the pair of side walls.

10. A method of assembling a cable assembly, comprising the steps of:
providing an insulative housing having a recess formed on a rear surface thereof and a plurality of contacts disposed in the insulative housing;
connecting, through one-time soldering, a first and second PCBs and a cable;
stacking the first and second PCBs together by a back to back manner to form a printed circuit and inserting a front portion of the printed circuit board to the recess of the housing; and
providing a shielding member enclosing the insulative housing and the printed circuit board.

11. The method of assembling the cable assembly as recited in claim 10, wherein the steps of connecting comprises:
providing a holding tool;
providing a wire management member, a first PCB and a second PCB located upon the holding tool, the wire management member disposed behind the first and second PCBs and having a plurality of slots formed on a top surface thereof, the first and second PCBs arranged along a transversal direction, each PCB defining a plurality of rear conductive pads being in alignment with the corresponding slots of the wire management member along a front to rear direction;
providing a cable having a plurality of conductive wires therein and assembled to the wire management member, each conductive wire passing through the corresponding slot and having a conductor therein and located upon the corresponding rear conductive pad of the printed circuit board; and
soldering the conductors of the wires to the rear conductive pads of the printed circuit board through hotbar process.

12. The method of assembling the cable assembly as recited in claim 10, wherein each contact defines a terminating section electrically connected to a front conductive pad formed on the front portion of the printed circuit board.

13. The method of assembling the cable assembly as recited in claim 10, wherein the shielding member comprises a first shell and a second shell assembled to the first shell.

14. An electrical cable connector assembly comprising:
an insulative housing including a mating port defining a mating cavity with first and second rows of contacts by opposite upper and lower sides of the mating cavity;
first and second printed circuit boards closely arranged with each other in a back-to-back parallel relation under condition that inner surfaces of said first and second printed circuit boards face toward each other while outer surfaces of said first and second printed circuit boards face away from each other;
rear portions of the first row of contacts mechanically and electrically connected to a front region of the outer surface of the first printed circuit board;
rear portions of the second row of contacts mechanically and electrically connected to a front region of the outer surface of the second printed circuit board;
a first set of wires mechanically and electrically connected to a rear region of the outer surface of the first printed circuit board; and
a second set of wires mechanically and electrically connected to a rear region of the outer surface of the second printed circuit board.

15. The electrical cable connector assembly as claimed in claim 14, wherein said first printed circuit board and said second printed circuit board are directly stacked with each other.

16. The electrical cable connector assembly as claimed in claim 15, wherein each of said first row of contacts includes a front deflected section extending forwardly into the mating cavity, and a rear straight section extending rearward along a horizontal direction in the housing and further seated upon the corresponding front region of the outer surface of the first printed circuit board.
